(19) United States
(12) Patent Application Publication
(10) Pub. No.: US 2020/0161525 A1
(43) Pub. Date: May 21, 2020

(54) THERMOELECTRIC MATERIAL, THERMOELECTRIC CONVERSION MODULE USING A THERMOELECTRIC MATERIAL, METHOD OF PRODUCING THE SAME, AND PELTIER ELEMENT

(71) Applicant: NATIONAL INSTITUTE FOR MATERIALS SCIENCE, Tsukuba-shi, Ibaraki (JP)

(72) Inventors: Norifusa SATOH, Tsukuba-shi, Ibaraki (JP); Takao MORI, Tsukuba-shi, Ibaraki (JP); Masaji OTSUKA, Tsukuba-shi, Ibaraki (JP)

(21) Appl. No.: 16/632,772

(22) PCT Filed: Jun. 27, 2018
(86) PCT No.: PCT/JP2018/024272

§ 371 Date: Jan. 21, 2020

(30) Foreign Application Priority Data
Jul. 18, 2017 (JP) 2017-138701

(51) Int. Cl. H01L 35/24; H01L 35/32; H01L 35/34

(52) U.S. Cl. CPC H01L 35/24; H01L 35/34; H01L 35/32

(57) ABSTRACT

[Object] To provide a thermoelectric material that reduces, when a thermoelectric conversion module is formed therefrom, contact resistance with an electrode and will not be peeled; the thermoelectric conversion module using the thermoelectric material; a method of producing the same, and a Peltier device.

[Solving Means] A thermoelectric material according to the present invention includes a thermoelectric substance and a solvent, and the solvent has a vapor pressure of 0 Pa or more and 1.5 Pa or less at 25° C., has a storage elastic modulus G′ a range of 1×10¹ Pa or more and 4×10⁶ Pa or less, and has a loss elastic modulus G″ in a range of 5 Pa or more and 4×10⁶ Pa or less.

### TECHNICAL FIELD

The present invention relates to a thermoelectric material, a thermoelectric conversion module using the thermoelectric material, a method of producing the same, and a Peltier element.

### BACKGROUND ART

In even our country of the world, where energy saving has advanced, approximately ¾ of the primary supply energy is discarded as thermal energy in the waste heat recovery. Under such circumstances, thermoelectric power generation elements are attracting attention as solid elements capable of recovering thermal energy and directly converting the thermal energy into electrical energy.

Since the thermoelectric power generation elements are direct conversion elements into electrical energy, they have advantages such as facilitating maintenance without moving parts, and scalability. For this reason, material research has been actively conducted on thermoelectric semiconductors.

Heat of 200° C. or less forms the maximum unused heat. A sheet-like thermoelectric material is suitable for recovering such so-called poor heat. In particular, there is an application in a wearable manner using body heat as uses that can create a high added value. However, not only having a sheet-like shape but also having flexibility is required for practical use (see, for example, Patent Literature 1 and Non-Patent Literature 2).

In Patent Literature 1, there is a method of using a thin-film thermoelectric material by using a flexible sheet as a substrate. However, as demerits, it can be predicted that the thermoelectric material will easily peel from the substrate and there is a concern that the thermoelectric material is not so durable. Further, a method of applying a thermoelectric material to a flexible substrate by an inkjet method or the like has been reported in, for example, Non-Patent Literatures 1 and 2. Although the resistance to peeling is somewhat improved, it has not been completely solved. Further, since thermoelectric materials represented by those in Patent Literature 1, Non Patent Literature 1, and Non-Patent Literature 2 are solid thermoelectric materials. Then, a process such as bringing an electrode material such as gold into adherence to the thermoelectric material in atomic by a physical vapor deposition method such as sputtering or applying a conductive paste including gold or silver to the surface of the thermoelectric material in advance is required in order to reduce contact resistance to an electrode.

Further, a sheet-type thermoelectric conversion module using an organic material has been developed (see, for example, Non-Patent Literature 3, and Non-Patent Literature 4). Non-Patent Literature 3 reports a sheet-type thermoelectric conversion module using poly(4-styrenesulfonic acid) or poly(3,4-ethylenedioxythiophene) (PEDOT:PSS or PEDOT:Tos) doped with tosylate as a thermoelectric material. Further, according to Non-Patent Literature 4, it has been reported that removing PSS in PEDOT:PSS improves the thermoelectric performance.

However, the sheet-type thermoelectric conversion module in Non-Patent Literature 3 has a thickness of 30 μm or more to maintain a temperature difference necessary for power generation, the thickness being thicker than that of another organic flexible device. For this reason, in the case of bending the sheet-type thermoelectric conversion module in Non-Patent Literature 3, a problem that an electrode is peeled or an electrode is disconnected due to the difference in curvature caused by the thick film occurs. Further, also in this case, the above-mentioned process has been required in order to reduce contact resistance between the thermoelectric material and the electrode, similarly to Patent Literature 1, Non-Patent Literature2, and Non-Patent Literature 3.

Further, even if the thermoelectric material in Non-Patent Literature 4 is used, not only the problem of peeling or disconnection of an electrode is not solved but also a process of removing PSS by washing in order to improve the thermoelectric performance is further required, which makes it more complicated.

Meanwhile, there has been known a technology for controlling the molecular arrangement of PEDOT:PSS (see, for example, Non-Patent Literature 5). According to Non-Patent Literature 5, it has been reported that the orientation control of PEDOT:PSS has been successful by mixing PEDOT:PSS with EMIM:X (EMIM:1-ethyl-3-methylimidazolium, X=chlorine, ethyl sulfate, tricyanomethane, tetracyanoborate anion) as an ionic liquid and the conductivity has been improved by 5000 times. However, although Non-Patent Literature 5 shows that such a mixture is used for an anode electrode of an organic thin film solar cell, it is desirable to develop further applications.

### CITATION LIST

### Patent Literature

Patent Literature 1: Japanese Patent No. 3981738

### Non-Patent Literature

Non-Patent Literature 1: Z. Lu et.al, Small 10,17,3551-3554,2014

Non-Patent Literature 2: S. J. Kim et.al, Energy Environ.Sci.,7,1959-1965,2014

Non-Patent Literature 3: O.Bubnova et.al, Nature Materials,10,429-433,2011

Non-Patent Literature 4: G-H.Kim et.al, Nature Materials,12,719-723,2013

Non-Patent Literature 5: S.Keeet.al, Adv.Mater.,28,8625-8631,2016

### DISCLOSURE OF INVENTION

### Technical Problem

It is an object of the present invention to provide a thermoelectric material that reduces contact resistance with an electrode and that will not be peeled when a thermoelectric conversion module is formed therefrom; the thermoelectric conversion module using the thermoelectric material; a method of producing the same, and a Peltier element.

### Solution to Problem

A thermoelectric material according to the present invention includes: a thermoelectric substance; and a solvent, in which the solvent has a vapor pressure of 0 Pa or more and 1.5 Pa or less at 25° C., has a storage elastic modulus G′ a range of 1×10¹ Pa or more and 4×10⁶ Pa or less, and has a loss elastic modulus G″ in a range of 5 Pa or more and 4×10⁶ Pa or less. This achieves the above-mentioned object.

The thermoelectric material may have the storage elastic modulus G′ in a range of 1×10³ Pa or more and 3.6×10⁶ Pa or less and the loss elastic modulus G″ in a range of 1×10³ Pa or more and 3.5 ×10⁶ Pa or less.

A volume ratio of the thermoelectric substance to the thermoelectric substance and the solvent may be in a range of 3% or more and 90% or less.

The volume ratio of the thermoelectric substance to the thermoelectric substance and the solvent may be in a range of 20% or more and 60% or less.

The thermoelectric substance may be selected from the group consisting of an organic material, an inorganic material, a metal material, composites thereof, and mixtures thereof.

The organic material may be a doped or undoped conductive polymer.

The conductive polymer may be selected from the group consisting of poly-3,4-ethylenedioxythiophene (PEDOT), polyaniline, polyacetylene, polyphenylin, polyfuran, polyselenophene, polythiophene, polyacene, polyisothianaphthene, polyphenylene sulfide, polyphenylene vinylene, polythiophene vinylene, polyperinaphthalene, polyanthracene, polynaphthalene, polypyrene, polyazulene, polypyrrole, polyparaphenylene, poly(benzobisimidazobenzophenanthroline), organoboron polymer, polytriazole, perylene, carbazole, triarylamine, tetrathiafulvalene, derivatives thereof, and copolymers thereof.

The solvent may further include an ion adsorbent.

The organic material may be a low molecular semiconductor.

The low molecular semiconductor may be selected from the group consisting of bithiophene, tetrathiafulvalene, anthracene, pentacene, rubrene, coronene, phthalocyanine, porphyrin, perylene dicarboximide, derivatives thereof, and combinations of molecular skeletons thereof.

The inorganic material may be an oxide ceramic, and the oxide ceramic may be selected from the group consisting of ZnO, SrTiO₃, NaCo₂O₄, Ca₃Co₄O₉, SnO₂, Ga₂O₃, CdO, In₂O₃, NiO, CeO₂, MnO, MnO₂, TiO₂, and complex oxides thereof.

The inorganic material may be a carbon-based material, and the carbon-based material may be selected from the group consisting of a carbon nanotube, a carbon nanorod, a carbon nanowire, graphene, a fullerene, and derivatives thereof.

The metal material may be selected from the group consisting of a metal, a semimetal, and an intermetallic compound.

The organic material may be a charge transfer complex, and the charge transfer complex may be a combination of a donor substance that is tetrathiafulvalene (TTF) or a derivative thereof, and an acceptor substance selected from the group consisting of tetracyanoquinodimethane (TCNQ), dicyanoquinone diimine (DCNQI), tetracyanoethylene (TCNE), and derivatives thereof.

The mixture may be an organic-inorganic hybrid material, and the organic-inorganic hybrid material may include an inorganic material selected from the group consisting of Bi—(Te, Se), Si—Ge, Pb—Te, GeTe—AgSbTe, (Co, Ir, Ru)—Sb, and (Ca, Sr, Bi) Co₂O₅, and an organic material selected from the group consisting of doped or undoped poly-3,4-ethylenedioxythiophene (PEDOT), polyaniline, polyacetylene, polyphenylin, polyfuran, polyselenophene, polythiophene, polyacene, polyisothianaphthene, polyphenylene sulfide, polyphenylene vinylene, polythiophene vinylene, polyperinaphthalene, polyanthracene, polynaphthalene, polypyrene, polyazulene, polypyrrole, polyparaphenylene, poly(benzobisimidazobenzophenanthroline), an organoboron polymer, polytriazole, perylene, carbazole, triarylamine, tetrathiafulvalene, derivatives thereof, and copolymers thereof.

The solvent may be an ionic liquid.

The ionic liquid may include a cation selected from the group consisting of imidazolium, pyridinium, pyrrolidinium, phosphonium, ammonium, and sulfonium, and an anion selected from the group consisting of a halogen, a carboxylate, a sulfate, a sulfonate, a thiocyanate, an aluminate, a phosphate, a phosphinate, an amide, an antimonate, an imide, a methanide, and a methid.

The solvent may be an organic solvent selected from the group consisting of an alkylamine (carbon number being 11-30), a fatty acid (carbon number being 7-30), a hydrocarbon (carbon number being 12-35), an alcohol (carbon number being 7-30), a polyether (molecular weight of 100 to 10,000), derivatives thereof, and a silicone oil.

The solvent may be an alkylamine that is tri-n-octylamine or tris(2-ethylhexyl) amine, or a fatty acid that is oleic acid.

Further, a solution to which a non-volatile solute has been added to lower the vapor pressure of the solution may be used, or a substance that melts into a solution at a thermoelectric power generation temperature or in the case where heat is applied when the substance is bonded to an electrode even if it is a solid at room temperature may be used. Conversely, the solvent component in the viscous thermoelectric material may solidify after being bonded to the electrode in order to achieve a sufficiently low vapor pressure.

A thermoelectric conversion module according to the present invention includes: a plurality of p-type thermoelectric conversion elements; and a plurality of n-type thermoelectric conversion elements, in which each of the plurality of p-type thermoelectric conversion elements and the plurality of n-type thermoelectric conversion elements includes the thermoelectric material according to any one of claims 1 to 15. This achieves the above-mentioned object.

The plurality of p-type thermoelectric conversion elements and the plurality of n-type thermoelectric conversion elements may include a plurality of partition walls and a plurality of lower electrodes, and are alternately positioned via the plurality of partition walls on the lower electrodes in a mold having elasticity and insulation, the plurality of p-type thermoelectric conversion elements and the plurality of n-type thermoelectric conversion elements may include a plurality of upper electrodes formed on an opposite side to a side on which the plurality of p-type thermoelectric conversion elements and the plurality of n-type thermoelectric conversion elements are in contact with the plurality of lower electrodes, and the p-type thermoelectric conversion element and the n-type thermoelectric conversion element make a pair, and the plurality of p-type thermoelectric conversion elements and the plurality of n-type thermoelectric conversion elements may be connected in series.

The mold may be formed of a material selected from the group consisting of an epoxy resin, a fluoropolymer, an imide resin, an amide resin, an ester resin, a nitrile resin, a chloroprene resin, an acrylonitrile-butadiene resin, an ethylene-propylene-diene resin, an ethylene propylene rubber, a butyl rubber, an epichlorohydrin rubber, an acrylic rubber, a polyvinyl chloride, a silicone rubber, derivatives thereof, copolymers thereof, and cross-linked products thereof.

The thickness of each of the plurality of p-type thermoelectric conversion elements and the plurality of n-type thermoelectric conversion elements may be in the range of 10 μm or more and 5 mm or less.

The upper electrode may be a metal foil or a sealing sheet including wiring.

A method of producing a thermoelectric conversion module including a plurality of p-type thermoelectric conversion elements and a plurality of n-type thermoelectric conversion elements according to the present invention includes using the thermoelectric material according to any one of claims 1 to 15 for each of the plurality of p-type thermoelectric conversion elements and the plurality of n-type thermoelectric conversion elements. This achieves the above-mentioned obj ect.

The method may further include: a step of depositing the thermoelectric material on lower electrodes in a mold so that the plurality of p-type thermoelectric conversion elements and the plurality of n-type thermoelectric conversion elements are alternately arranged, the mold including a plurality of partition walls and the lower electrodes formed between the plurality of partition walls; and a step of forming upper electrodes on the deposited thermoelectric material, in which the step of forming the upper electrodes includes pressing a metal foil or a printed wiring on a sealing sheet, the upper electrode being the metal foil or the printed wiring on a sealing sheet.

A Peltier element according to the present invention uses a thermoelectric material being the thermoelectric material described above. This achieves the above-mentioned object.

### Advantageous Effects of Invention

The thermoelectric material according to the present invention is characterized by having viscosity by including a thermoelectric substance and a solvent. The present inventors have found by own ingenuity that the thermoelectric performance of a thermoelectric substance can be maintained even in a viscous state in which the thermoelectric substance and a solvent are mixed with each other. The thermoelectric material according to the present invention includes a solvent having a vapor pressure of 0 Pa or more and 1.5 Pa or less at 25° C., or a boiling point of 250° C. or more under the atmospheric pressure. By using such a thermoelectric material for a thermoelectric conversion module, it is possible to provide long-term stable thermoelectric performance and thermoelectric conversion module in which a solvent does not substantially volatilize.

Further, since the thermoelectric material according to the present invention has a storage elastic modulus G′ in the range of 1×10¹ Pa or more and 4×10⁶ Pa or less and a loss elastic modulus G″ in the range of 5 Pa or more and 4×10⁶ Pa or less, the thermoelectric material is excellent in adhesiveness. Therefore, by simply pressing a material to be an electrode to the thermoelectric material according to the present invention, an upper electrode of a thermoelectric conversion module can be formed, and excellent adhesion to an electrode by a viscosity is achieved. Therefore, an additional process, e.g., deposition of an electrode by physical vapor deposition such as sputtering or application of a conductive paste including gold or silver, or an additional material, which have been required to reduce contact resistance in the past as described above, is unnecessary. As a result, the production process and components of the thermoelectric conversion module can be simplified, and thus, it is possible to provide a thermoelectric conversion module at a low cost. Since contact resistance is reduced, it is possible to achieve a high power factor and increase the amount of power generation. Further, by using such a thermoelectric material for a sheet-type flexible thermoelectric conversion module, the thermoelectric material deforms, following bending of the module. Thus, the electrode is not peeled or disconnected.

### BRIEF DESCRIPTION OF DRAWINGS

FIG. 1 is a schematic diagram showing a thermoelectric conversion module according to the present invention.

FIG. 2 is a flowchart for producing the thermoelectric conversion module according to the present invention.

FIG. 3 is another flowchart for producing the thermoelectric conversion module according to the present invention.

### MODE(S) FOR CARRYING OUT THE INVENTION

Hereinafter, embodiments of the present invention will be described with reference to the drawings. Note that similar components will be denoted by similar reference symbols, and description thereof will be omitted.

### Embodiment 1

In an embodiment 1, a thermoelectric material according to the present invention and a method of producing the thermoelectric material will be described.

The thermoelectric material according to the present invention includes a thermoelectric substance and a solvent, and has a viscosity. As a result, the above-mentioned effects are exhibited. It has been known from the past that a thermoelectric substance which is a solid having a high density is advantageous because of the conduction mechanism thereof. However, the present inventors have overturned the technical conventional thinking and have found that the thermoelectric substance maintains the thermoelectric performance even in a liquid state, i.e., even if it has a viscosity by being mixed in a powder state with a solvent.

Note that as described above, although Non-Patent Literature 5 discloses a mixture of PEDOT:PSS and EMIM:X, the thermoelectric performance of the mixture is not disclosed at all, and the present inventors have found, by ingenuity, the thermoelectric performance for the first time and have found using it for a thermoelectric material, a favorable viscosity for functioning as a thermoelectric material, and a favorable mixing ratio.

In the present invention, the solvent has a vapor pressure of 0 Pa or more and 1.5 Pa or less at 25° C. As a result, even in the case where the thermoelectric material is exposed to an environment in which it is normally used, the solvent does not substantially volatilize, and thus, long-term stable thermoelectric performance can be exhibited. In the present specification, for simplicity, the solvent having a boiling point of 250° C. or more under the atmospheric pressure may be determined as a solvent having a vapor pressure of 0 Pa or more and1.5 Pa or less at 25° C. As a result, it is possible to easily determine whether or not a solvent with no accurate information regarding a vapor pressure can be used the present invention.

The thermoelectric material according to the present invention is excellent in adhesiveness because the viscosity of the thermoelectric material is adjusted so that a storage elastic modulus G′ is in the range of 1×10¹ Pa or more and 4×10⁶ Pa or less and a loss elastic modulus G″ is in the range of 5 Pa or more and 4×10⁶ Pa or less. In the case where the storage elastic modulus G′ is less than 1 ×10¹ Pa and the loss elastic modulus G″ is less than 5 Pa, when the thermoelectric material is used for a thermoelectric conversion module, the adhesion with the electrode is not sufficient in some cases. In the case where the storage elastic modulus G′ exceeds 4×10⁶ Pa and the loss elastic modulus G″ exceeds 4×10⁶ Pa, the viscosity is too high, which can make the thermoelectric material difficult to handle.

More favorably, the thermoelectric material according to the present invention has the storage elastic modulus G in the range of 1×10³ Pa or more and 3.6×10⁶ Pa or less and the loss elastic modulus G″ in the range of 1×10³ Pa or more and 3.5 ×10⁶ Pa or less. With this range, it is possible to achieve excellent adhesiveness with the electrode and reduce contact resistance with the electrode, maintaining high thermoelectric performance even at a high temperature.

Favorably, in the thermoelectric material according to the present invention, the volume ratio of a thermoelectric substance to the thermoelectric substance and a solvent is in the range of 3% or more and 90% or less. With this range, it is possible to achieve low contact resistance and exhibit thermoelectric performance, maintaining the above-mentioned viscosity. More favorably, the volume ratio of the thermoelectric substance to the thermoelectric substance and the solvent is in the range of 20% or more and 60% or less. With this range, it is possible to achieve further low contact resistance and exhibit high thermoelectric performance, maintaining the above-mentioned viscosity.

In the present invention, arbitrary thermoelectric substances can be adopted. Among them, the thermoelectric substance is favorably selected from the group consisting of an organic material, an inorganic material, a metal material, composites thereof, and mixtures thereof, which have thermoelectric performance. With these materials, thermoelectric performance is exhibited when forming a thermoelectric conversion module.

In the present invention, the thermoelectric substance only needs to be mixed with a solvent, and does not need to melt. From this viewpoint, the thermoelectric substance favorably has a particle size in the range of 10 nm or more and 100 μm or less. With this range, the thermoelectric substance and the solvent are mixed with each other, and thermoelectric performance is exhibited, maintaining a viscosity. The thermoelectric substance favorably has a particle size in the range of 0.1 μm or more and 20 μm or less. With this range, the thermoelectric substance and the solvent are uniformly mixed with each other, and thus, high thermoelectric performance is exhibited. Note that the particle size is a volume-based median diameter (D50).

The organic material is favorably a doped or undoped conductive polymer. A dopant is a p-type or n-type dopant or an arbitrary dopant appropriately selected for improving thermoelectric performance. By adopting a conductive polymer, high thermoelectric performance is expected and excellent mixability with various solvents is achieved.

The conductive polymer is favorably selected from the group consisting of poly-3,4-ethylenedioxythiophene (PEDOT), polyaniline, polyacetylene, polyphenylin, polyfuran, polyselenophene, polythiophene, polyacene, polyisothianaphthene, polyphenylene sulfide, polyphenylene vinylene, polythiophene vinylene, polyperinaphthalene, polyanthracene, polynaphthalene, polypyrene, polyazulene, polypyrrole, polyparaphenylene, poly(benzobisimidazobenzophenanthroline), organoboron polymer, polytriazole, perylene, carbazole, triarylamine, tetrathiafulvalene, derivatives thereof, and copolymers thereof.All of these conductive polymers are known to have high thermoelectric performance. Among them, a thiophene-based conductive polymer is expected to achieve thermoelectric performance. More favorably, PEDOT is a p-type one, which has high thermoelectric performance. PEDOT may include, as a dopant, polystyrene sulfonic acid (PSS), tosylate (Tos), or the like. As a result, the conductivity is improved and solubility in a solvent is imparted, which makes it easy to produce a thermoelectric material.

The solvent may favorably further include an ion adsorbent. In the case of a doped conductive polymer, the ion adsorbent is capable of removing the dopant from the conductive polymer to improve thermoelectric performance. Examples of such an ion adsorbent include aluminum hydroxide, hydrotalcite (e.g., Mg₁₋ₓAlₓ(OH)₂(CO₃),_{x/2}.mH₂O(0<x<1)), magnesium silicate, aluminum silicate, and a solid solution of aluminum oxide and magnesium oxide. In particular, in the case where the conductive polymer is PEDOT-PSS (PSS-doped PEDOT), it is favorable that the solvent further includes an ion adsorbent because PSS is removed from PEDOT and the original thermoelectric performance of PEDOT can be exhibited. Note that since PSS can be removed from PEDOT by simply adding an ion adsorbent, removal of PSS by washing typified by that in Non-Patent Literature 4 is unnecessary. Then, the process is reduced and it is advantageous.

The ion adsorbent is added so that the pH of the solution including the conductive polymer is 1 or more and 8 or less. As a result, it is possible to remove the dopant and improve thermoelectric performance. More favorably, the ion adsorbent is added so that the pH is 5 or more and 8 or less. The ion adsorbent favorably mixes with a conductive polymer solution well and has a small size with a large surface area to adsorb the dopant from the viewpoint of removal of the dopant. The ion adsorbent only needs to have a particle size in the range of 1μm or more and 100 μm or less, for example.

The organic material may be a low molecular semiconductor having a molecular weight is lower than that of the above-mentioned conductive polymer. Also the low molecular semiconductor exhibits thermoelectric performance. For example, the low molecular semiconductor is selected from the group consisting of bithiophene, tetrathiafulvalene, anthracene, pentacene, rubrene, coronene, phthalocyanine, porphyrin, perylene dicarboximide, derivatives thereof, and combinations of molecular skeletons thereof. Each of these low molecular semiconductors has high thermoelectric performance and is excellent in mixability with various solvents.

The organic material may be a charge transfer complex having thermoelectric performance. The charge transfer complex includes a combination of a donor substance and an acceptor substance, and includes, for example, a combination of a donor substance that is tetrathiafulvalene (TTF) or a derivative thereof, and an acceptor substance selected from the group consisting of tetracyanoquinodimethane (TCNQ), dicyanoquinone diimine (DCNQI), tetracyanoethylene (TCNE), and derivatives thereof. Each of these charge transfer complexes has high thermoelectric performance.

The inorganic material is favorably an oxide ceramic having thermoelectric performance. For example, the oxide ceramic is selected from the group consisting of ZnO, SrTiO₃, NaCo₂O₄, Ca₃Co₄O₉, SnO₂, Ga₂O₃, CdO, In₂O₃, NiO, CeO₂, MnO, MnO₂, TiO₂, and complex oxides thereof. Each of these oxide ceramics is favorable because it has thermoelectric performance, is commercially available, and is available.

The inorganic material is favorably an arbitrary carbon-based material that includes carbon and has thermoelectric performance. For example, the carbon-based material is selected from the group consisting of a carbon nanotube, a carbon nanorod, a carbon nanowire, graphene, a fullerene, and derivatives thereof. These carbon-based materials are known to have high thermoelectric performance and are favorable. The carbon nanotube may include a single layer or a multilayer. The derivatives are intended to modify the surface of functional groups or substituents. The functional groups or substituents are appropriately selected in order to impart a desired function such as dispersibility and solubility.

Examples of the metal material include a metal, an intermetallic compound, and a semimetal, which have thermoelectric performance. Examples of the metal include bismuth, antimony, lead, and tellurium. The intermetallic compound or semimetal is favorably selected from the group consisting of a tellurium compound, a silicide compound, an antimony compound, a gallium compound, an aluminum compound, a sulfide, and a rare earth compound. These metal materials are known to have high thermoelectric performance and are favorable.

Examples of the tellurium compound include PbTe, Bi₂Te₃, AgSbTe₂, GeTe, and Sb₂Te₃. Examples of the silicide compound include SiGe, β-FeSi₂, Ba₈Si₄₆, Mg₂Si, MnSi_{1.73}, Ce—Al—Si, and a Ba—Ga—Al—Si-based clathrate compound. Examples of the antimony compound include ZnSb, Zn₄Sb₃, CeFe₃CoSb₁₂, and LaF₃CoSb₁₂. Examples of the gallium compound include Ba—Ga—Sn and Ga—In—Sb. Examples of the aluminum compound include NiAl and an Fe—V—Al-based Heusler compound. Examples of the sulfide include TiS₂ and TiS₃. Examples of the rare earth compound include CeRhAs.

The mixture may be a mixture of arbitrary materials of the above-mentioned organic materials, inorganic materials, or metal materials, or a mixture of one of these material and another material. Examples of the mixture include an organic-inorganic hybrid material including the above-mentioned organic material and inorganic material. For example, the organic-inorganic hybrid material includes an inorganic material selected from the group consisting of Bi—(Te, Se), Si—Ge, Pb—Te, GeTe—AgSbTe, (Co, Ir, Ru)—Sb, and (Ca, Sr, Bi)Co₂O₅, and an organic material selected from the group consisting of doped or undoped poly-3,4-ethylenedioxythiophene (PEDOT), polyaniline, polyacetylene, polyphenylin, polyfuran, polyselenophene, polythiophene, polyacene, polyisothianaphthene, polyphenylene sulfide, polyphenylene vinylene, polythiophene vinylene, polyperinaphthalene, polyanthracene, polynaphthalene, polypyrene, polyazulene, polypyrrole, polyparaphenylene, poly(benzobisimidazobenzophenanthroline), organoboron polymer, polytriazole, perylene, carbazole, triarylamine, tetrathiafulvalene, derivatives thereof, and copolymers thereof. With these organic-inorganic hybrid materials, high thermoelectric performance and excellent mixability with various solvents are achieved.

The composite may be a composite of arbitrary materials of the above-mentioned organic materials, inorganic materials, or metal materials, or a composite of one of these materials and another material. For example, TiS₂ may be used as a metal material and an organic material may be intercalated between the layers of TiS₂. For example, an arbitrary material of the above-mentioned organic materials, inorganic materials, or metal materials may be encapsulated with another material to form one particle.

The solvent is favorably an ionic liquid. The ionic liquid has a vapor pressure of substantially 0 Pa at 25° C. and does not volatilize. The ionic liquid is not particularly limited, and only needs to be an ionic liquid including, for example, a cation selected from the group consisting of imidazolium, pyridinium, pyrrolidinium, phosphonium, ammonium, and sulfonium, and an anion selected from the group consisting of a halogen, a carboxylate, a sulfate, a sulfonate, a thiocyanate, an aluminate, a phosphate, a phosphinate, an amide, an antimonate, an imide, a methanide, and a methid. Each of these ionic liquids forms, by being mixed with the above-mentioned thermoelectric substance, a thermoelectric material having a viscosity, maintaining thermoelectric performance.

The solvent may be favorably an organic solvent selected from the group consisting of an alkylamine (carbon number being 11 to 30), a fatty acid (carbon number being 7 to 30), a hydrocarbon (carbon number being 12 to 35), an alcohol (carbon number being 7 to 30), a polyether (molecular weight being 100 to 10,000), derivatives thereof, and a silicone oil. Examples of the alkylamine include tri-n-octylamine and tris(2-ethylhexyl) amine. Examples of the fatty acid include oleic acid. Each of these organic solvent has a vapor pressure of 0 Pa or more and 1.5 Pa or less at 25° C., or a boiling point in the rage of 250° C. or more under the atmospheric pressure, and does not volatilize under a normal use environment (e.g., 40° C. to 120° C.). Note that two or more types of these organic solvents may be combined or any of these organic solvents may be combined with the above-mentioned ionic liquid for use.

In the embodiment 1, although whether each thermoelectric substance is a p-type one or n-type one is not specified, those skilled in the art could easily determine the conductivity type of the selected thermoelectric substance.

The thermoelectric material according to the present invention may include another additive in addition to a thermoelectric substance and a solvent. For example, the other additive is a surfactant, antioxidant, a thickener, a heat stabilizer, a dispersant, or the like, but is not limited as long as it does not affect thermoelectric performance. It is favorable that the additive is non-volatile because the vapor pressure is reduced. Further, a substance that melts into a solution at a thermoelectric power generation temperature or in the case where heat is applied when the substance is bonded to an electrode is favorable even if it is a solid at room temperature, because the vapor pressure is further reduced. Conversely, the vapor pressure may be reduced by solidifying the solvent component in the viscous thermoelectric material after being bonded to the electrode within the range that does not impair the flexibility of the module.

An arbitrary solvent having a vapor pressure of 0 Pa or more and 1.5 Pa or less at 25° C. can be used as the solvent as described above. Among them, it has been stated that an ionic liquid or a predetermined organic solvent is favorable. On the other hand, as the solvent according to the present invention, a solution prepared by adding a non-volatile solute to a dispersion medium and adjusting the vapor pressure at 25° C. to 0 Pa or more and 1.5 Pa or less may be used. Alternatively, a non-volatile solute may be added to the ionic liquid or predetermined organic solvent to further reduce the vapor pressure. The solute and the dispersion medium may be selected in accordance with Raoult's law. For example, tetradecane and cholesterol stearate may be combined with each other.

Next, an exemplary method of producing the above-mentioned thermoelectric material according to the present invention will be described.

The thermoelectric material according to the present invention can be obtained by mixing the above-mentioned thermoelectric substance and the above-mentioned solvent with each other. Since only mixing is necessary, a special apparatus and a skilled engineer are unnecessary, which is advantageous for practical use. The mixing may be performed manually, or a machine such as a blender and a mixer may be used. Note that being visually uniform can be regarded as being sufficiently mixed for simplicity. In the case of using a machine, being mixed under normal stirring conditions can be regarded as being sufficiently mixed.

The above-mentioned thermoelectric substance may be pulverized by wet or dry, using a grinding machine such as a ball mill and a jet mill before mixing the above-mentioned thermoelectric substance and the above-mentioned solvent with each other. As a result, a thermoelectric substance having a uniform particle size (e.g., in the range of 10 nm or more and 100 μm or less) can be obtained, and thus, the thermoelectric substance can be mixed with the solvent uniformly.

The thermoelectric substance and the solvent are mixed with each other so that the volume ratio of the thermoelectric substance to the thermoelectric substance and the solvent is in the range of 3% or more and 90% or less, favorably, 20% or more and 60% or less. As a result, a thermoelectric material having the above-mentioned effects is produced.

In order to promote uniform mixing, a dispersion medium such as methanol, acetonitrile, dichloromethane, tetrahydrofuran (THF), ethylene carbonate, diethyl carbonate, y-butyrolactone, and acetone is added in addition to the above-mentioned solvent, and the dispersion medium may be removed by heating/natural drying or the like after being mixed. In the case where the solvent is an ionic liquid, since the dispersion media dissolves the ionic liquid, mixing with the thermoelectric substance can be promoted in the case where, for example, the amount of ionic liquid is little. Also in the case where the solvent is the above-mentioned organic solvent, the compatibility between the organic solvent and the dispersion medium only needs to be considered.

Favorably, in the case where the thermoelectric substance is a doped conductive polymer, the above-mentioned ion adsorbent may be further mixed. In this case, the ion adsorbent is added so that the pH of the solution including the conductive polymer is 1 or more and 8 or less (favorably, 5 or more and 8 or less). As a result, it is possible to reliably remove the dopant and improve thermoelectric performance. In particular, since the dopant can be removed at the time of producing a thermoelectric material without separately performing washing for removing the dopant unlike Non-Patent Literature 4, the production is simple and advantageous for practical use.

### Embodiment 2

In an embodiment 2, a thermoelectric conversion module using the thermoelectric material according to the present invention described in the embodiment 1, and a method of producing the thermoelectric conversion module will be described.

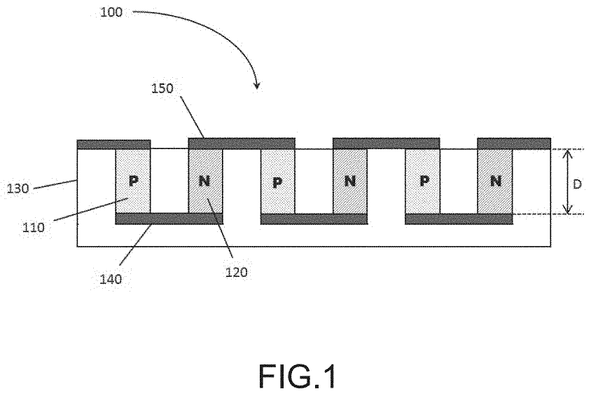

FIG. 1 is a schematic diagram showing a thermoelectric conversion module according to the present invention.

A thermoelectric conversion module 100 includes a plurality of p-type thermoelectric conversion elements 110 and a plurality of n-type thermoelectric conversion elements 120, and each of the p-type thermoelectric conversion element 110 and the n-type thermoelectric conversion element 120 includes a viscous thermoelectric material. In this embodiment, the viscous thermoelectric material is described as including the thermoelectric material described in the embodiment 1. The present inventors have found for the first time that a so-called liquid thermoelectric material having a viscosity is applicable to a thermoelectric conversion module. A thermoelectric material to be used for a thermoelectric conversion module has been a solid material from the past, and there has been no idea of using a thermoelectric material having a viscosity. This is because there has been no thermoelectric material having a viscosity and it has been believed that a thermoelectric substance which is a solid having a high density is advantageous because of the conduction mechanism thereof. In addition, in the case of using a solid inorganic material, metal wax only needs to be used for contact with an electrode and the contact resistance has not caused a problem. However, using metal wax requires a temperature of 450° C. or more, so that it is difficult to adapt to a flexible thermoelectric conversion module.

The present inventors have overturned conventional thinking, and challenged the construction of a new module, and succeeded in dramatically reducing the contact resistance without using an expensive silver paste or metal wax and dramatically improving the flexibility of the thermoelectric conversion module. As a result, the thermoelectric conversion module can closely adhere in accordance with the shape of the heat source, and thus, it is unnecessary to individually produce the thermoelectric conversion module in accordance with the shape of the heat source unlike the existing solid thermoelectric material, which enables mass production and cost reduction. Therefore, it is advantageous for practical use.

Since the thermoelectric material having a viscosity described in the embodiment 1 is used as described above, the thermoelectric material forming the p-type thermoelectric conversion element 110 and the n-type thermoelectric conversion element 120 follows the bending of the thermoelectric conversion module 100 and is deformed. Thus, the electrode is not peeled or disconnected. Further, since the thermoelectric material includes a solvent having a vapor pressure of 0 Pa or more and 1.5 Pa or less at 25° C., the thermoelectric material does not substantially evaporate and the thermoelectric performance is maintained semi-permanently. Therefore, it is possible to provide a stable thermoelectric conversion module.

Note that the combination of the p-type and n-type thermoelectric materials to be applied to the p-type thermoelectric conversion element 110 and the n-type thermoelectric conversion element 120 is not particularly limited, and can be appropriately selected by those skilled in the art. For example, PEDOT and TCNQ-TTF can be respectively selected as the p-type thermoelectric material and the n-type thermoelectric material. It should be understood that this combination is merely an example and there are an infinite number of possible combinations from the above-mentioned thermoelectric materials.

In the thermoelectric conversion module 100, favorably, each of the plurality of p-type thermoelectric conversion elements 110 and the plurality of n-type thermoelectric conversion elements 120 is disposed in a mold 130 formed of an insulating material. In the case where a portion of the mold 130 between the p-type thermoelectric conversion element 110 and the n-type thermoelectric conversion element 120 is regarded as a partition wall, the mold 130 includes a plurality of partition walls and a plurality of lower electrode 140, and the plurality of p-type thermoelectric conversion elements 110 and the plurality of n-type thermoelectric conversion elements 120 are alternately positioned via the plurality of partition walls on the plurality of lower electrode 140.

Further, in the thermoelectric conversion module 100, the plurality of p-type thermoelectric conversion elements 110 and the plurality of n-type thermoelectric conversion elements 120 have a plurality of upper electrodes 150 formed so that the p-type thermoelectric conversion element 110 and the n-type thermoelectric conversion element 120 make a pair on the side opposed to the side on which they are in contact with the plurality of lower electrode 140. Here, the plurality of p-type thermoelectric conversion elements 110 and the plurality of n-type thermoelectric conversion elements 120 are connected in series via the plurality of lower electrode 140 and the plurality of upper electrodes 150.

It is desirable that the mold 130 is formed of a material further having elasticity and stretchability. As a result, the thermoelectric conversion module 100 can have flexibility. Note that the material of the mold 130 is not particularly limited as long as the material is an insulating material, but favorably has heat resistance, weather resistance, and low gas permeability depending on the user environment. Examples of such a material include a material selected from the group consisting of an epoxy resin, a fluoropolymer, an imide resin, an amide resin, an ester resin, a nitrile resin, a chloroprene resin, an acrylonitrile-butadiene resin, an ethylene-propylene-diene resin, an ethylene propylene rubber, a butyl rubber, an epichlorohydrin rubber, an acrylic rubber, polyvinyl chloride, a silicone rubber, derivatives thereof, copolymers thereof, and cross-linked products thereof. Among them, it is favorable to select a material formed of a thermosetting elastomer, a non-diene rubber, and a fluoropolymer because it has elasticity, heat resistance, and weather resistance in addition to insulation.

Each of the plurality of p-type thermoelectric conversion elements 110 and the plurality of n-type thermoelectric conversion elements 120 has a thickness of 10 μm or more (corresponding to a length D in FIG. 1). In the case where the length D is 10 μm or more, the temperature difference necessary for power generation can be maintained. Although there is no upper limit, it is favorable that the upper limit is 5 mm or less from the aspect at the time of normal use. Since the thermoelectric material according to the present invention is used for the p-type thermoelectric conversion element 110 and the n-type thermoelectric conversion element 120, the upper electrode 150 is not peeled or disconnected even if the length D is 10 μm or more and a difference in curvature between the lower electrode 140 side and the upper electrode 150 side is generated when bending occurs. More favorably, the thickness D is in the range of 20 μm or more and 1 mm or less. As a result, it is possible to provide the thermoelectric conversion module 100 having flexibility, maintaining stable high thermoelectric performance.

Although the mold 130 is shown as a flat plate including partition walls in FIG. 1, since the thermoelectric material is a thermoelectric substance having a viscosity as described above, the mold may be curved as long as it has a recessed portion formed by a partition wall that can be filled with the thermoelectric material.

The material of each of the lower electrode 140 and the upper electrode 150 is not particularly limited as long as it is a material having thermal conductivity and electrical conductivity. For example, the material is selected from the group consisting of metal materials including Al, Cr, Fe, Co, Ni, Cu, Zn, Nb, Mo, In, Ta, W, Ir, Pt, Au, Pd, and alloys thereof, transparent conductors including tin-doped indium oxide (ITO), zinc oxide (ZnO), Ga-doped zinc oxide (GZO), Al-doped zinc oxide (AZO), zinc-doped indium oxide (IZO), In—Ga—Zn—O (IGZO), antimony-doped tin oxide (ATO), and graphene, and conductive polymers including polyacetylene, poly(p-phenylene vinylene), polypyrrole, polythiophene, polyaniline, and poly(p-phenylene sulfide).

The thickness of each of the lower electrode 140 and the upper electrode 150 is not limited, but is, for example, in the range of 100 nm or more and 50 μm or less. With this range, the electrode itself is not damaged or disconnected even if the thermoelectric conversion module 100 is bent.

In particular, the upper electrode 150 may be a metal foil or printed wiring on a sealing sheet formed of the above-mentioned material having thermal conductivity and electrical conductivity. The sealing sheet may be formed of, for example, the material that is the same as that of the mold 130.

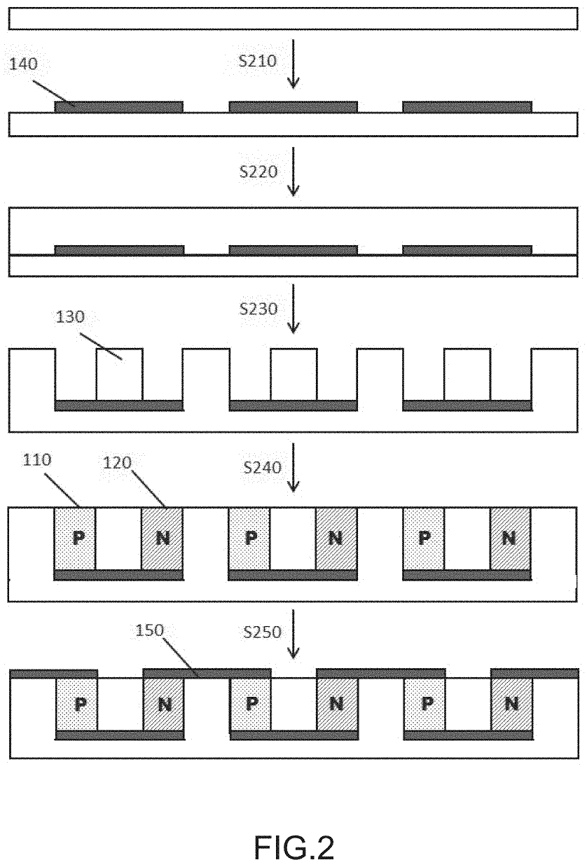

Next, an exemplary process for producing the thermoelectric conversion module 100 according to the present invention will be described with reference to FIG. 2.

FIG. 2 is a flowchart for producing the thermoelectric conversion module according to the present invention.

Step S210: A material, which has insulation and, favorably, elasticity, stretchability, and becomes a part of a mold, is prepared, and the plurality of lower electrode 140 is formed on the material. Since the material having insulation and, favorably, elasticity and stretchability, is as described above, description thereof will be omitted. Further, although a mold material having a flat plate shape is shown in FIG. 2, a curved plate material may be used instead of the flat plate. Here, for simplicity, description will be made as a flat plate.

In order to obtain the plurality of lower electrode 140, for example, a mask is disposed on the flat plate, and the material having thermal conductivity and electrical conductivity is provided by physical vapor deposition, chemical vapor deposition, dip coating, spin coating, or the like. In the case where the material having thermal conductivity and electrical conductivity is a metal material or a transparent conductor, it is possible to adopt an existing semiconductor process technology. In the case where the material having thermal conductivity and electrical conductivity is a conductive polymer or graphene, dip coating or spin coating is favorable.

Step S220: After forming the plurality of lower electrode 140, the plurality of lower electrode 140 is covered with the material having insulation and, favorably, elasticity and stretchability. Here, the case where the material having insulation and, favorably elasticity is a material to be used for a positive photoresist and a semiconductor process technology is applied will be described.

Step S230: After applying the positive photoresist, a mask pattern is transferred to the positive photoresist by an exposure apparatus to which a mask is attached. After that, when the solution is applied, only the exposed portion is melted. In this way, the mold 130 including partition walls is formed.

Step S240: The hole portion of the mold 130 is filled with the thermoelectric material according to the present invention via the partition walls so that the p-type one and the n-type one are alternately arranged. In this way, the plurality of p-type thermoelectric conversion elements 110 and the plurality of n-type thermoelectric conversion elements 120 are formed.

Step S250: The plurality of upper electrodes 150 is formed. The plurality of upper electrodes 150 is formed on the side opposed to the side on which the plurality of p-type thermoelectric conversion elements 110 and the plurality of n-type thermoelectric conversion elements 120 are in contact with the plurality of lower electrode 140 so that the plurality of p-type thermoelectric conversion elements 110 and the plurality of n-type thermoelectric conversion elements 120 are connected in series.

The plurality of upper electrodes 150 may be formed by physical vapor deposition and chemical vapor deposition as in the past. In the present invention, since a viscous thermoelectric material is used, by simply pressing a metal foil or a printed wiring on a sealing sheet, it is possible to form an electrode having high adhesion to a thermoelectric material and reduced contact resistance. In this way, the thermoelectric conversion module 100 according to the present invention is produced.

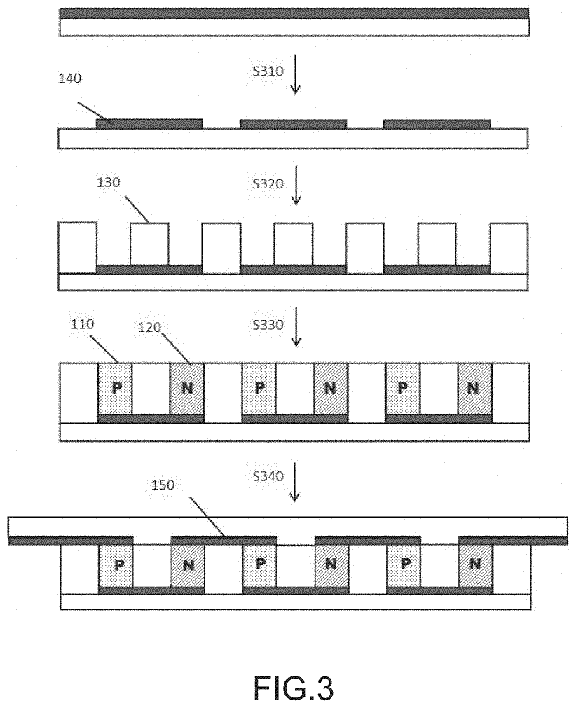

FIG. 3 is another flowchart for producing the thermoelectric conversion module according to the present invention.

Step S310: A raw substrate provided with a metal foil (region shown in black in the figure) such as a copper foil on an insulating substrate (region shown in white in the figure) that becomes a part of a mold such as a glass epoxy resin and bakelite is prepared. Etching is performed so that a predetermined region of the metal foil of the raw substrate is left, and thus, the plurality of lower electrode 140 is formed. In the etching, a region to be a lower electrode (or an upper electrode) is masked, and a region that is not masked is removed by an etchant. Note that the etchant is appropriately selected in accordance with the type of the metal foil but an aqueous iron chloride solution can be used in the case where the metal foil is formed of copper, for example.

Step S320: A material having insulation and, favorably, flexibility and stretchability, which forms partition walls of the mold is prepared, and a hole is made with a punch or the like. The remained portion that is not removed by the punch forms partition walls, and the portion removed by the punch forms the hole portion to be filled with a thermoelectric material. The mold 130 having the hole is adhered to the substrate obtained in Step S310. In this way, the mold 130 including partition walls is formed.

Step S330: The hole portion of the mold 130 is filled with the thermoelectric material according to the present invention via the partition walls so that the p-type one and the n-type one are alternately arranged. This Step is similar to Step S240 in FIG. 2, description thereof is omitted.

Step S340: The plurality of upper electrodes 150 is formed. Specifically, the substrate including a plurality of upper electrodes obtained in the procedure similar to that in Step S310 is bonded on the thermoelectric material so that the plurality of p-type thermoelectric conversion elements 110 and the plurality of n-type thermoelectric conversion elements 120 are connected in series.

Using the thermoelectric material according to the present invention eliminates the necessity for an expensive dedicated apparatus for performing physical vapor deposition or chemical vapor deposition for deposition of an upper electrode, and thus, the production cost of the thermoelectric conversion module can be reduced. Further, since also a conductive paste or the like for reducing contact resistance between the upper electrode and the thermoelectric material can be eliminated, also the components of the thermoelectric conversion module can be simplified.

Although the process for producing the mold 130 has been described with reference to Step S210 to S230 and Step S310 to S320 in FIG. 2 and FIG. 3, respectively, a commercially available mold may be adopted and the process may be started from Step S240 and Step S330.

Although a thermoelectric conversion module using the thermoelectric material according to the present invention has been described with reference to FIG. 1 to FIG. 3, those skilled in the art would understand that the thermoelectric material according to the present invention may be used for a Peltier element that generates a temperature difference using a potential difference applied to a thermoelectric material, in contrast to the thermoelectric conversion module. Note that also such a Peltier element can adopt a known structure.

Next, the present invention will be described in detail using specific Examples, but it should be noted that the present invention is not limited to the Examples.

### EXAMPLE

[Material]

Materials used in the subsequent Examples and Comparative Examples will be described. Note that all the materials were special grade reagents and were used without purification. 1-ethyl-3-methylimidazolium trifluoromethanesulfonate (EMIM Otf) and 1-ethyl-3-methylimidazolium tricyanomethanide (EMIM TCM) were purchased from Tokyo Chemical Industry Co., Ltd., and 1-ethyl-3-methylimidazolium tetrafluoroborate (EMIM TFB) and 1-methyl-1-propylpyrrolidinium bis(trifluoromethanesulfonyl) imide (MPP FSI) were purchased from Wako Pure Chemical Industries, Ltd. Any of these is an ionic liquid having a vapor pressure of substantially 0 (<1.5 Pa or less) at 25° C.

Isopropyl alcohol (IPA) and trimethylamine were purchased from Kanto Chemical Co., Ltd., tri-n-octylamine, tris(2-ethylhexyl) amine, oleic acid, and dimethyl sulfoxide (DMSO) were purchased from Sigma-Aldrich Co. LLC., and hexylamine was purchased from Tokyo Chemical Industry Co., Ltd. Each of tri-n-octylamine and tris(2-ethylhexyl) amine has a vapor pressure of less than 1.5 Pa at 25° C. However, DMSO has a vapor pressure of 84 Pa at 25° C.

Tetracyanoquinodimethane-tetrathiafulvalene (TCNQ-TTF) was purchased from Tokyo Chemical Industry Co., Ltd., and poly(3,4-ethylenedioxythiophene) doped with poly(styrene sulfonate) (PEDOT:PSS) was purchased from Sigma-Aldrich Co. LLC.

Mg_{4.5}Al₂(OH)₁₃CO₃.3.5H₂O was purchased from Kyowa Chemical Industry Co., Ltd., a fullerene (C60) and a carbon nanotube (CNT) were purchased from Tokyo Chemical Industry Co., Ltd., and bismuth was purchased from Sigma-Aldrich Co. LLC. Titanium sulfide (TiS₂) was synthesized by a chemical vapor transport method.

### Example 1

In Example 1, thermoelectric materials obtained by mixing TCNQ-TTF(density: 1.6 g/cm³) that is an organic material and EMIM Otf that is an ionic liquid as a thermoelectric substance and a solvent, respectively, at various volume ratios ware produced, and viscoelastic properties and thermoelectric properties were evaluated.

TCNQ-TTF was dispersed in IPA and pulverized with a ball mill. The particle size of TCNQ-TTF after the pulverization was in the range of 0.5 μm to 2 μm. TCNQ-TTF and EMIM Otf were mixed under the conditions shown in Table 1, and samples 1-1 to 1-7 were prepared.

TABLE 1
Production conditions of samples 1-1 to 1-7 in Example 1

| Sample in | | | | | | | Volume |
|---|---|---|---|---|---|---|---|
| Example 1 | Thermoelectric substance | | | Ionic iquid | | | ratio [%] |
| Sample 1-1 | TCNQ-TTF | 4 | mg | EMIM Otf | 0.5 | μl | 83.33 |
| Sample 1-2 | TCNQ-TTF | 4 | mg | EMIM Otf | 1 | μl | 71.43 |
| Sample 1-3 | TCNQ-TTF | 4 | mg | EMIM Otf | 2 | μl | 55.56 |
| Sample 1-4 | TCNQ-TTF | 4 | mg | EMIM Otf | 5 | μl | 33.33 |
| Sample 1-5 | TCNQ-TTF | 4 | mg | EMIM Otf | 10 | μl | 20.00 |
| Sample 1-6 | TCNQ-TTF | 4 | mg | EMIM Otf | 20 | μl | 11.11 |
| Sample 1-7 | TCNQ-TTF | 4 | mg | EMIM Otf | 50 | μl | 4.76 |

Next, viscoelasticity evaluation was performed on the samples 1-1 to 1-7 from which IPA had been removed. For the evaluation, a viscoelasticity measuring device (manufactured by Anton Paar, model number MCR301) was used. The results are shown in Table 2.

Next, thermoelectric property evaluation was performed on the samples 1-1 to 1-7. For the evaluation, a 2 mm square frame having a height of 70 to 80 μm was prepared, with a photoresist (SU-8), on a silicon substrate on which gold (electrode) had been deposited , and the frame was filled with the respective samples 1-1 to 1-7. After the filling, the silicon substrate was heated at 40° C., and IPA was removed. After that, a copper electrode (metal foil) was attached to the upper portion for sealing. The resistance values of the samples 1-1 to 1-7 and the temperature dependence of the thermoelectromotive voltage were measured using a digital multimeter (manufactured by CUSTOM, model number CDM-2000D). The resistance values were measured at room temperature, and the thermoelectromotive voltage was measured from 40° C. to 130° C. in increments of 10° C. The results are shown in Table 3.

TABLE 2
Results of viscoelasticity measurement of samples 1-1 to 1-7 in Example 1

| Sample in | Volume | Storage elastic | Loss elastic | Complex |
|---|---|---|---|---|
| Example 1 | ratio [%] | modulus [Pa] | modulus [Pa] | viscosity [Pa · s] |
| Sample 1-1 | 83.33 | 3.50 × 10⁶ | 3.18 × 10⁶ | 4.73 × 10⁷ |
| Sample 1-2 | 71.43 | 3.61 × 10⁶ | 3.53 × 10⁶ | 5.05 × 10⁷ |
| Sample 1-3 | 55.56 | 3.55 × 10⁶ | 3.22 × 10⁶ | 4.79 × 10⁷ |
| Sample 1-4 | 33.33 | 1.75 × 10³ | 1.86 × 10³ | 2.55 × 10⁴ |
| Sample 1-5 | 20.00 | 1.04 × 10³ | 9.48 × 10² | 1.41 × 10⁴ |
| Sample 1-6 | 11.11 | 4.07 × 10¹ | 4.71 × 10¹ | 6.22 × 10² |
| Sample 1-7 | 4.76 | 1.28 × 10¹ | 8.79 × 10⁰ | 1.55 × 10² |

TABLE 3
Measurement results of thermoelectric properties of samples 1-1 to 1-7 in Example 1

| Sample in | Volume ratio | Resistance | Thermoelectromotive voltage [mV] | | | | | | | | | |
|---|---|---|---|---|---|---|---|---|---|---|---|---|
| Example 1 | [%] | value [Ω] | 40° C. | 50° C. | 60° C. | 70° C. | 80° C. | 90° C. | 100° C. | 110° C. | 120° C. | 130° C. |
| Sample 1-1 | 83.33 | 20 | 0.3 | 0.3 | 0.4 | 0.5 | 0.6 | 0.8 | 0.9 | 1.0 | 1.1 | 1.4 |
| Sample 1-2 | 71.43 | 20 | 0.3 | 0.3 | 0.4 | 0.4 | 0.6 | 0.8 | 0.9 | 1.0 | 1.1 | 1.3 |
| Sample 1-3 | 55.56 | 12 | 0.3 | 0.3 | 0.4 | 0.4 | 0.5 | 0.7 | 0.7 | 0.9 | 1.2 | 1.6 |
| Sample 1-4 | 33.33 | 16 | 0.3 | 0.4 | 0.5 | 0.7 | 0.9 | 1.2 | 1.4 | 1.9 | 2.0 | 2.6 |
| Sample 1-5 | 20.03 | 8 | 0.3 | 0.3 | 0.5 | 0.5 | 0.6 | 0.8 | 0.8 | 0.8 | 1.1 | 1.2 |
| Sample 1-6 | 11.11 | 14 | 0.3 | 0.3 | 0.4 | 0.5 | 0.6 | 0.5 | 0.7 | 0.7 | 0.7 | 0.7 |
| Sample 1-7 | 4.76 | 27 | 0.3 | 0.3 | 0.4 | 0.3 | 0.6 | 0.6 | 0.5 | 0.6 | 0.4 | 0.7 |

In accordance with Table 2 and Table 3, all of the samples 1-1 to1-7 had a low resistance value of 30Ω or less, and showed a tendency for the absolute value of the thermoelectromotive voltage to increase as the temperature increased, and power generation was confirmed. From this fact, it was confirmed that the samples 1-1 to 1-7 had viscoelasticity of the storage elastic modulus G′ in the range of 1×10¹ Pa or more and 4×10⁶ Pa or less and the loss elastic modulus G″ in the range of 5 Pa or more and 4×10⁶ Pa or less and were thermoelectric materials.

Considering application of the thermoelectric material to the thermoelectric conversion module, it is desirable that the resistance value is low and the absolute value of the thermoelectromotive voltage is not reduced even at a high temperature. From this fact, it was shown that having the storage elastic modulus G′ the range of 1×10³ Pa or more and 3.6×10⁶ Pa or less and the loss elastic modulus G″ in the range of 1×10³ Pa or more and 3.5×10⁶ Pa or less excluding the samples 1-1, 1-2, 1-6, and 1-7 from the samples listed in Table 2 and Table 3 is particularly desirable. With this range, the resistance value is less than 20 Ω and the absolute value of the thermoelectromotive voltage is not reduced. More favorably, in accordance with the samples 1-3 to 1-5, it was shown that the thermoelectric substance in the thermoelectric material was in the range of 20% or more and 60% or less.

### Example 2

In Example 2, thermoelectric materials obtained by mixing PEDOT:PSS that is an organic material, various ionic liquids, and Mg_{4.5}Al₂(OH)₁₃CO₃.3.5H₂O as necessary as a thermoelectric substance, a solvent, and an ion adsorbent, respectively were produced, and thermoelectric properties were evaluated.

As shown in Table 4, 20 μL of various ionic liquids were added to 100 μL of PEDOT:PSS (1% aqueous solution). Note that in the case of adding an ion adsorbent, 2.7 mg of the ion adsorbent was added to 1000 μL of PEDOT:PSS (1% aqueous solution) so as to have a pH of 8, and an ionic liquid was added after stirring for 24 hours. Any of the obtained samples 2-1 to 2-4 had viscoelasticity of the storage elastic modulus G′ the range of 1×10¹ Pa or more and 4×10⁶ Pa or less and the loss elastic modulus G″ in the range of 5 Pa or more and 4×10⁶ Pa or less.

TABLE 4
Production conditions of samples 2-1 to 2-4 in Example 2

| Sample in Example 2 | Thermoelectric substance | | Ionic liquid | | Ion absorbent | Volume ratio [%] |
|---|---|---|---|---|---|---|
| Sample 2-1 | PEDOT:PSS(1% aqueous solution) | 100 μL | EMIM TCM | 20 μL | | 33.33 |
| Sample 2-2 | PEDOT:PSS(1% aqueous solution) | 100 μL | EMIM TCM | 20 μL | 2.7 mg | 48.44 |
| Sample 2-3 | PEDOT:PSS(1% aqueous solution) | 100 μL | EMIM TFB | 20 μL | 2.7 mg | 48.44 |
| Sample 2-4 | PEDOT:PSS(1% aqueous solution) | 100 μL | EMIM FSI | 20 μL | 2.7 mg | 48.44 |

Thermoelectric property evaluation was performed on the samples 2-1 to 2-4 in the same way as that in Example 1. The thermoelectromotive voltage was measured from 40° C. to 100° C. in increments of 10° C. The results are shown in Table 5.

TABLE 5
Measurement results of thermoelectric properties of samples 2-1 to 2-4 in Example 2

| Sample in | Volume ratio | Resistance | Thermoelectromotive voltage [mV] | | | | | | |
|---|---|---|---|---|---|---|---|---|---|
| Example 2 | [%] | value [Ω] | 40° C. | 50° C. | 60° C. | 70° C. | 80° C. | 90° C. | 100° C. |
| Sample 2-1 | 33.33 | 2.5 | −0.1 | −0.2 | −0.2 | −0.2 | −0.3 | −0.3 | −0.3 |
| Sample 2-2 | 48.44 | 30 | −0.1 | −0.3 | −0.4 | −0.4 | −0.6 | −0.6 | −0.7 |
| Sample 2-3 | 48.44 | 20 | −0.1 | −0.3 | −0.3 | −0.7 | −0.6 | −0.9 | −1.3 |
| Sample 2-4 | 48.44 | 70 | −0.2 | −0.3 | −0.5 | −0.5 | −0.6 | −0.7 | −0.9 |

In accordance with Table 5, all of the samples 2-1 to 2-4 showed a tendency for the absolute value of the thermoelectromotive voltage to increase as the temperature increased, and power generation was confirmed. From this fact, it was confirmed that the samples 2-1 to 2-4 had viscoelasticity of the storage elastic modulus G′ the range of 1×10¹ Pa or more and 4×10⁶ Pa or less and the loss elastic modulus G″ in the range of 5 Pa or more and 4×10⁶ Pa or less and were thermoelectric materials.

When comparing the sample 2-1 and the sample 2-2 with each other, the absolute value of the thermoelectromotive voltage increased by using an ion adsorbent, and it was shown that thermoelectric properties improved. From this fact, it was confirmed that the dopant (here, PSS) could be removed and the original thermoelectric properties of the thermoelectric substance could be exhibited by adding an ion adsorbent. When comparing the samples 2-2 and 2-3 with the sample 2-4, since the resistance value is reduced, it is suggested that an imidazolium-based ionic liquid is favorable as a solvent of the thermoelectric material according to the present invention.

### Example 3

In Example 3, thermoelectric materials obtained by mixing an inorganic material, a metal material, or a composite as a thermoelectric substance, an ionic liquid (EMIM TCM) as a solvent, and an antioxidant (oleic acid) as necessary were produced and thermoelectric properties were evaluated.

Similarly to Example 1, various thermoelectric substances were dispersed in IPA and pulverized with a ball mill. The particles size of any of the thermoelectric materials after the pulverization was in the range of 0.5 μm to 10 μm. As shown in FIG. 6, an ionic liquid was added to various thermoelectric substances. Note that in the case of adding an antioxidant, the antioxidant was added at the time of a ball mill, washed with IPA before adding the ionic liquid, and removed.

Further, TiS₂ was mixed with trimethylamine (201 μL) and hexylamine (201 μL), and they are intercalated between the layers of TiS₂. Note that since excess trimethylamine and hexylamine that were not intercalated volatilize, they are not considered in the volume ratio.

All of the obtained samples 3-1 to 3-5 had viscoelasticity of the storage elastic modulus G′ in the range of 1×10¹ Pa or more and 4×10⁶ Pa or less and the loss elastic modulus G″ in the range of 5 Pa or more and 4×10⁶ Pa or less.

TABLE 6
Production conditions of samples 3-1 to 3-5 in Example 3

| Sample in Example 3 | Thermoelectric substance | | Ionic liquid | | Antioxidant | Volume ratio [%] |
|---|---|---|---|---|---|---|
| Sample 3-1 | C60 | 20 mg | EMIIV TCM | 20 μL | — | 37.74 |
| Sample 3-2 | CNT | 20 mg | EMIIV TCM | 3 μL | — | 77.82 |
| Sample 3-3 | Bismuth | 480 mg | EMIIV TCM | 60 μL | 400 μL | 44.99 |
| Sample 3-4 | *¹TiS₂ | 180 mg | EMIIV TCM | 90 μL | — | 38.31 |
| Sample 3-5 | *²TiS₂ | 180 mg | EMIIV TCM | 90 μL | — | 38.31 |

*¹TiS₂ is mixed with trimethylamine, which is intercalated between layers
*²T1S₂ is mixed with hexylamine, which is intercalated between layers

Thermoelectric property evaluation was performed on the samples 3-1 to 3-5 in the same way as that in Example 1. The thermoelectromotive voltage was measured from 40° C. to 130° C. in increments of 10° C. The results are shown in Table 7.

TABLE 7
Measurement results of thermoelectric properties of samples 3-1 to 3-5 in Example 3

| Sample in | Volume | Resistance | Thermoelectromotive voltage [mV] | | | | | | | | | |
|---|---|---|---|---|---|---|---|---|---|---|---|---|
| Example 3 | ratio [%] | value [Ω] | 40° C. | 50° C. | 60° C. | 70° C. | 80° C. | 90° C. | 100° C. | 110° C. | 120° C. | 130° C. |
| Sample 3-1 | 37.74 | 50 | 90 | 100 | 110 | 120 | 110 | 140 | 140 | 240 | 160 | 160 |
| Sample 3-2 | 77.82 | 1.4 | −0.5 | −0.5 | −0.8 | −1.2 | −0.2 | −2.1 | −1.4 | −1.7 | −1.6 | −1.9 |
| Sample 3-3 | 44.99 | 1 | 0.2 | 0.3 | 0.5 | 0.6 | 0.7 | 0.8 | 0.8 | 1.1 | 2.2 | 1.8 |
| Sample 3-4 | 38.31 | 3 | 0.4 | 0.9 | 1.4 | 1.6 | 1.6 | 1.6 | 1.8 | 2.4 | 2.5 | 2.4 |
| Sample 3-5 | 35.31 | 13 | 0.8 | 1.4 | 2.1 | 2.5 | 2.9 | 3.2 | 5.4 | 6.6 | 7.9 | 8.4 |

In accordance with Table 7, all of the samples 3-1˜3-5 showed a tendency for the absolute value of the thermoelectromotive voltage to increase as the temperature increased, and power generation was confirmed. From this fact, it was confirmed that the samples 3-1 to 3-5 had viscoelasticity of the storage elastic modulus G′ the range of 1×10¹ Pa or more and 4×10⁶ Pa or less and the loss elastic modulus G″ in the range of 5 Pa or more and 4×10⁶ Pa or less and were thermoelectric materials.

In accordance with the results of Example 1 to Example 3, it was shown that a thermoelectric substance that can be used as the thermoelectric material according to the present invention was an organic material, an inorganic material, a metal material, a composite thereof, or the like, which exhibits thermoelectric properties.

### Example 4

In Example 4, thermoelectric material obtained by mixing a composite (TiS₂ intercalated with an organic compound) or metal material (bismuth) as a thermoelectric substance and an organic solvent as a solvent were produced and thermoelectric properties were evaluated.

Similarly to Example 1, the thermoelectric substances were dispersed in IPA and pulverized with a ball mill. The particle size of any of thermoelectric materials after the pulverization was in the range of 0.5 μm to 2 μm for TiS₂ and 5 μm to 20 μm for bismuth. As shown in Table 8, 703 μL of the organic solvent was added to TiS₂ (1200 mg) and 50 μL of oleic acid was added to bismuth (60 mg). All of the samples 4-1 to 4-3 had viscoelasticity of the storage elastic modulus G′ the range of 1×10¹ Pa or more and 4×10⁶ Pa or less and the loss elastic modulus G″ in the range of 5 Pa or more and 4×10⁶ Pa or less.

TABLE 8
Production conditions of samples 4-1 to 4-3 in Example 4

| Sample in | Thermoelectric | | | | | | Volume |
|---|---|---|---|---|---|---|---|
| Example 4 | substance | | | Organic solvent | | | ratio [%] |
| Sample 4-1 | TiS₂ | 1200 | mg | Tri-n-octylamine | 703 | μL | 34.66 |
| Sample 4-2 | TiS₂ | 1200 | mg | Tris(2-ethylhexyl) | 703 | μL | 34.66 |
| | | | | amine | | | |
| Sample 4-3 | Bismuth | 60 | mg | Oleic acid | 50 | μL | 10.92 |

Thermoelectric property evaluation was performed on the samples 4-1 to 4-3 in the same way as that in Example 1. The thermoelectromotive voltage was measured from 40° C. to 130° C. in increments of 10° C. for the sample 4-1 and the sample 4-2 and from 40° C. to 110° C. in increments of 10° C. for the sample 4-3. The results are shown in Table 9.

TABLE 9
Measurement results of thermoelectric properties of samples 4-1 to 4-3 in Example 4

| Sample in | Volume ratio | Resistance | Thermoelectromotive voltage [mV] | | | | | | | | | |
|---|---|---|---|---|---|---|---|---|---|---|---|---|
| Example 4 | [%] | value [Ω] | 40° C. | 50° C. | 60° C. | 70° C. | 80° C. | 90° C. | 100° C. | 110° C. | 120° C. | 130° C. |
| Sample 4-1 | 34.63 | 4.1 | 1.4 | 2.5 | 1.1 | 0.7 | 1.8 | 1.3 | 2 | 0.9 | 2.1 | 3.4 |
| Sample 4-2 | 34.66 | 3.5 | 0.8 | 1.5 | 1.1 | 1.5 | 1.9 | 2.4 | 2.3 | 2.3 | 4.5 | 7.3 |
| Sample 4-3 | 10.92 | 1.4 | 1 | 0.8 | 0.9 | 0.9 | 0.9 | 1.1 | 1.1 | 1.3 | | |

In accordance with Table 9, all of the samples 4-1 to 4-3 showed a tendency for the absolute value of the thermoelectromotive voltage to increase as the temperature increased, and power generation was confirmed. From this fact, it was confirmed that the samples 4-1 to 4-3 had viscoelasticity of the storage elastic modulus G′ the range of 1×10¹ Pa or more and 4×10⁶ Pa or less and the loss elastic modulus G″ in the range of 5 Pa or more and 4×10⁶ Pa or less and were thermoelectric materials. Further, it was shown that for a solvent that could be used for the thermoelectric material according to the present invention, an ionic liquid, an organic solvent, and the like were not limited as long as the vapor pressure at 25° C. was 0 Pa or more and 1.5 Pa or less.

### Comparative Example 5

In Comparative Example 5, a thermoelectric element was produced in the same was as that in the case of the sample 1-5 in Example 1 except that the ionic liquid was not used, and thermoelectric properties were evaluated.

Attempts were made to evaluate thermoelectric properties of such a thermoelectric element. However, since TCNQ-TTF was a powder by itself and had no viscosity at all, an upper copper electrode (metal foil) similar to that in Example 1 could not be bonded well and measurement was not possible. In view of the above, the metal foil and TCNQ-TTF were brought into contact with each other using a silver paste. As a result, contact resistance was on the order of MΩ and it was necessary to further reduce the contact resistance.

### Comparative Example 6

In Comparative Example 6, a thermoelectric element was produced in the same way as that in the case of the sample 2-2 in Example 2 except that dimethyl sulfoxide (DMSO) (vapor pressure: 84 Pa, a temperature of 25° C., boiling point: 189° C., the atmospheric pressure) was used instead of an ionic liquid, and thermoelectric properties were evaluated.

In the case of heating such a thermoelectric element, adhesiveness was lost, the metal foil is peeled, and power generation could not be observed.

From the comparison between Examples 1 to 4 and Comparative Examples 5 and 6, it was shown that since the thermoelectric material according to the present invention included a thermoelectric substance and a solvent and had viscoelasticity of the storage elastic modulus G′ in the range of 1×10¹ Pa or more and 4×10⁶ Pa or less and the loss elastic modulus G″ in the range of 5 Pa or more and 4×10⁶ Pa or less, contact resistance could be reduced without requiring a conductive paste such as a silver paste, an electrode could be prevented from being peeled, and excellent power generation was possible.

### Example 7

In Example 7, a thermoelectric conversion module shown in FIG. 1 was produced using the thermoelectric material according to the present invention. The sample 1-4 in Example 1 and the sample 2-3 in Example 2 were used as an n-type thermoelectric material and a p-type thermoelectric material, respectively.

A mold that was obtained through Steps S210 to S230 in FIG. 2 or Steps S310 to S320 in FIG. 3 and included a gold electrode as a lower electrode and partition walls was used, and the hole portions formed by the partition walls were filled with the n-type thermoelectric material and the p-type thermoelectric material so that they were alternately arranged. Next, a copper electrode (metal foil) was bonded to form an upper electrode. Note that the number of cells was four, the mold was formed of a chloroprene rubber, and the thickness (D in FIG. 1) of each of the p-type thermoelectric conversion element and the n-type thermoelectric conversion element was 75 μm.

Using the same apparatus as that in Example 1, thermoelectric properties of the entire four cells were evaluated, and power generation of 12.2 mV at 40° C. could be observed. From this fact, it was shown that a thermoelectric conversion module could be realized using the thermoelectric material according to the present invention.

Next, this thermoelectric conversion module was bent with curvatures of diameters of 4.6 cm, 2.4 cm, and 1.1 cm, and the state at that time was observed to examine the change in resistance. Even in the case where the thermoelectric conversion module was bent with any curvature, the copper electrode was not peeled. In addition, the resistivity did not change.

From this fact, by adopting the thermoelectric material according to the present invention in a thermoelectric conversion module, high flexibility can be achieved because the electrode is not peeled or disconnected even in the case where the module is bent. Further, it was shown that by adopting the thermoelectric material according to the present invention in a thermoelectric conversion module, contact resistance with an electrode was reduced and thus, it was possible to achieve a high power factor and provide a thermoelectric conversion module having an increased amount of power generation.

### INDUSTRIAL APPLICABILITY

Since the thermoelectric material according to the present invention has a viscosity, contact resistance with an upper electrode is reduced when forming a thermoelectric conversion module, and the thermoelectric material is capable of efficiently taking in heat by being in close contact with and matching the shape of different pipes or reactors having different sizes in a factory where exhaust heat is exhausted in large quantities. Such a thermoelectric conversion module does not need to be individually produced in accordance with the shape of the heating device, mass production is possible. In addition, such characters that can maintain the performance even if the thermoelectric conversion module is bent can be said to be suitable for Roll-to-Roll in which mass production is possible in a continuous manner. Although process development for producing an organic thin film solar cell by Roll-to-Roll has been performed until now, it has not been put into practical use. One of the reasons is that an organic thin film solar cell has a problem in the durability, but it is also due to that the final product needs to be wound up with a Roll in the case of Roll-to-Roll. This is because it is generally difficult to guarantee the quality because a large difference in curvature occurs between the product wound up first and the product wound up last. Being strong in bending and not affecting performance make it possible to not only expand applications but also perform high-speed mass production and cost reduction by Roll-to-Roll.

### REFERENCE SIGNS LIST

100 thermoelectric conversion module

110 p-type thermoelectric conversion element

120 n-type thermoelectric conversion element

130 mold

140 lower electrode

150 upper electrode

1. A thermoelectric material, comprising:
a thermoelectric substance; and
a solvent, wherein
the solvent
has a vapor pressure of 0 Pa or more and 1.5 Pa or less at 25° C.,
has a storage elastic modulus G′ in a range of 1×10¹ Pa or more and 4×10⁶ Pa or less, and
has a loss elastic modulus G″ in a range of 5 Pa or more and 4×10⁶ Pa or less.

2. The thermoelectric material according to claim 1, wherein
the thermoelectric material has the storage elastic modulus G′ in a range of 1 ×10³ Pa or more and 3.6×10⁶ Pa or less and the loss elastic modulus G″ in a range of 1×10³ Pa or more and 3.5 ×10⁶ Pa or less.

3. The thermoelectric material according to claim 1, wherein
a volume ratio of the thermoelectric substance to the thermoelectric substance and the solvent is in a range of 3% or more and 90% or less.

4. The thermoelectric material according to claim 3, wherein
the volume ratio of the thermoelectric substance to the thermoelectric substance and the solvent is in a range of 20% or more and 60% or less.

5. The thermoelectric material according to claim 1, wherein
the thermoelectric substance is selected from the group consisting of an organic material, an inorganic material, a metal material, composites thereof, and mixtures thereof.

6. The thermoelectric material according to claim 5, wherein
the organic material is a doped or undoped conductive polymer.

7. The thermoelectric material according to claim 6 wherein
the conductive polymer is selected from the group consisting of poly-3,4-ethylenedioxythiophene (PEDOT), polyaniline, polyacetylene, polyphenylin, poly furan, polyselenophene, polythiophene, polyacene, polyisothianaphthene, polyphenylene sulfide, polyphenylene vinylene, polythiophene vinylene, polyperinaphthalene, polyanthracene, polynaphthalene, polypyrenc, polyazulene, polypyrrole, polyparaphenylene, poly(benzobisimidazobenzophenanthroline), organoboron polymer, polytriazole, perylene, carbazole, triarylamine, tetrathiafulvalene, derivatives thereof, and copolymers thereof.

8. The thermoelectric material according to claim 6, wherein
the solvent further includes an ion adsorbent.

9. The thermoelectric material according to claim 5, wherein
the inorganic material is a carbon-based material, and
the carbon-based material is selected from the group consisting of a carbon nanotube, a carbon nanorod, a carbon nanowire, graphene, a fullerene, and derivatives thereof.

10. The thermoelectric material according to claim 5, wherein
the metal material is selected from the group consisting of a metal, a semimetal, and an intermetallic compound.

11. The thermoelectric material according to claim 5, wherein
the organic material is a charge transfer complex, and
the charge transfer complex is a combination of a donor substance that is tetrathiafulvalene (TTF) or a derivative thereof, and an acceptor substance selected from the group consisting of tetracyanoquinodimethane (TCNQ), dicyanoquinone diimine (DCNQI), tetracyanoethylene (TCNE), and derivatives thereof.

12. The thermoelectric material according to claim 1, wherein
the solvent is an ionic liquid.

13. The thermoelectric material according to claim 12, wherein
the ionic liquid includes a cation selected from the group consisting of imidazolium, pyridinium, pyrrolidinium, phosphonium, ammonium, and sulfonium, and an anion selected from the group consisting of a halogen, a carboxylate, a sulfate, a sulfonate, a thiocyanate, an aluminate, a phosphate, a phosphinate, an amide, an antimonate, an imide, a methanide, and a methid.

14. The thermoelectric material according to claim 1, wherein
the solvent is an organic solvent selected from the group consisting of an alkylamine (carbon number being 11-30), a fatty acid (carbon number being 7-30), a hydrocarbon (carbon number being 12-35), an alcohol (carbon number being 7-30), a polyether (molecular weight of 100 to 10,000), derivatives thereof, and a silicone oil.

15. The thermoelectric material according to claim 14, wherein
the solvent is an alkylamine that is tri-n-octylamine or tris(2-ethylhexyl) amine, or a fatty acid that is oleic acid.

16. A thermoelectric conversion module, comprising:
a plurality of p-type theimoelectric conversion elements; and
a plurality of n-type thermoelectric conversion elements, wherein
each of the plurality of p-type thermoelectric conversion elements and the plurality of n-type thermoelectric conversion elements includes a thermoelectric material, and
the thermoelectric material, comprising:
a thermoelectric substance; and
a solvent, wherein the solvent
has a vapor pressure of 0 Pa or more and 1.5 Pa or less at 25° C.,
has a storage elastic modulus G′ in a range of 1 ×10¹ Pa or more and 4 ×10⁶ Pa or less. and
has a loss elastic modulus G″ in a range of 5 Pa or more and 4×10⁶ Pa or less.

17. The thermoelectric conversion module according to claim 16, wherein
the plurality of p-type thermoelectric conversion elements and the plurality of n-type thermoelectric conversion elements include a plurality of partition walls and a plurality of lower electrodes, and are alternately positioned via the plurality of partition walls on the lower electrodes in a mold having elasticity and insulation,
the plurality of p-type thermoelectric conversion elements and the plurality of n-type thermoelectric conversion elements include a plurality of upper electrodes formed on an opposite side to a side on which the plurality of p-type thermoelectric conversion elements and the plurality of n-type thermoelectric conversion elements are in contact with the plurality of lower electrodes, and the p-type thermoelectric conversion element and the n-type thermoelectric conversion element make a pair, and
the plurality of p-type thermoelectric conversion elements and the plurality of n-type thermoelectric conversion elements are connected in series.

18. The thermoelectric conversion module according to claim 17, wherein
the upper electrode is a metal foil or a sealing sheet including wiring.

19. A method of producing a thermoelectric conversion module including a plurality of p-type thermoelectric conversion elements and a plurality of n-type thermoelectric conversion elements, the method comprising:
using a thermoelectric material for each of the plurality of p-type thermoelectric conversion elements and the plurality of n-type thermoelectric conversion elements, wherein
the thermoelectric material, comprised:
a thermoelectric substance; and
a solvent, wherein
the solvent
has a vapor pressure of 0 Pa or more and 1.5 Pa or less at 25° C.,
has a storage elastic modulus G′ in a range of 1 ×10¹ Pa or more and 4×10⁶ Pa or less, and
has a loss elastic modulus G″ in a range of 5 Pa or more and 4×10⁶ Pa or less.

20. The method according to claim 19, further comprising:
a step of depositing the thermoelectric material on lower electrodes in a mold so that the plurality of p-type thermoelectric conversion elements and the plurality of n-type thermoelectric conversion elements are alternately arranged, the mold including a plurality of partition walls and the lower electrodes formed between the plurality of partition walls; and
a step of forming upper electrodes on the deposited thermoelectric material, wherein
the step of forming the upper electrodes includes pressing a metal foil or a sealing seal including wiring, the upper electrode being the metal foil or the sealing seal including wiring.

21. A Peltier element using a thermoelectric material, the thermoelectric material, and comprising:
a thermoelectric substance; and
a solvent, wherein
the solvent
has a vapor pressure of 0 Pa or more and 1.5 Pa or less at 25° C.,
has a storage elastic modulus G′ in a range of 1 ×10¹ Pa or more and 4×10⁶ Pa or less, and
has a loss elastic modulus G″ in a range of 5 Pa or more and 4×10⁶ Pa or less.
